(19) United States
(12) Patent Application Publication
(10) Pub. No.: US 2015/0144884 A1
(43) Pub. Date: May 28, 2015

(54) GRAPHENE FILM, ELECTRONIC DEVICE, AND METHOD FOR MANUFACTURING ELECTRONIC DEVICE

(71) Applicant: National Institute of Advanced Industrial Science and Technology, Tokyo (JP)

(72) Inventors: Junichi YAMAGUCHI, Atsugi (JP); Shintaro SATO, Atsugi (JP)

(73) Assignee: National Institute of Advanced Industrial Science and Technology, Tokyo (JP)

(21) Appl. No.: 14/550,045

(22) Filed: Nov. 21, 2014

(30) Foreign Application Priority Data
Nov. 22, 2013 (JP) 2013-242251

(51) Int. Cl. H01L 29/16; H01L 29/66; H01L 29/10; C01B 31/04; H01L 29/786

(52) U.S. Cl. CPC H01L 29/1606; C01B 31/0438; H01L 29/78696; H01L 29/1033; H01L 29/66045
USPC 257/29; 423/448; 428/220; 438/479

(57) ABSTRACT

A reliable graphene film that provides complete semiconductive properties without mixing of metallic properties, redacts an off current, achieves a high current on/off ratio of 10⁵ or more sufficient for practical use, and prevents variations in electric properties is obtained. In a grapheme film 3, a plurality of ribbon-shaped graphenes 3a having a longitudinal edge structure of as arm chair type constitute a network structure, and the grapheme 3a includes three or more six-membered rings of carbon atoms bonded in parallel in a short direction and has a width of 0.7 nm or more.

### CROSS-REFERENCE TO RELATED APPLICATION

This application is based upon and claims the benefit of priority of the prior Japanese Patent Application No. 2013-242251, filed on Nov. 22, 2013, the entire contents of which are incorporated here in by reference.

### FIELD

The present embodiment relates to a graphene film, an electronic device using the grapheme film, and a method for manufacturing the electronic device.

### BACKGROUND

There have been many studies on nanocarbon materials in the hope of next-generation electronics materials. Graphene that is a sheet-like two-dimensional material with cartoon, atoms being arranged in a honeycomb lattice, or a carbon nanotube (CNT) that is a one-dimensional material with graphene being rolled into a cylindrical shape have particularly attracted attention because of having many excellent electric, mechanical, thermal, and chemical properties.

The CNT includes a single-layer CNT with one cylindrical graphene layer, a multilayer CNT with two or more layers, and a bundle of the layers. The CNT provides semiconductive properties and metallic properties depending on chirality (helicity). Also, it is known that the CNT provides more metallic properties with the increase in the number of layers, and a single-layer CNT that provides particularly excellent performance and a multilayer CNT with a relatively small number of layers have been studied and developed.

For example, it has been reported that a field-effect transistor using, as a channel, one single-layer CNT providing semiconductive properties provides high performance (for example, see A. Bachtold et al., Science 234, 1317 (2001)). However, since a process for fabricating such a transistor handling one CNT requires high skills and time, it is difficult to put the process into practical use.

Thus, as an application with more simple process technology, a thin film transistor (TFT) using, as a channel, a random network with a plurality of CNTs being continuously in contact has attracted attention.

Generally, a CNT is synthesized to obtain a hybrid of a semiconductive CNT and a metallic CNT. For example, it has been theoretically clarified that ⅔ of the entire single-layer CNT provides semiconductive properties, and the remaining ⅓ provides metallic properties. Thus, to improve a current on/off ratio of a TFT using a CNT network, it is important to leave the semiconductive CNT and remove the metallic CNT from the CNT hybrid that constitutes the network.

Many methods for separating the semiconductive CNT from the metallic CNT have been proposed so far. For example, Japanese Laid-open Patent Publication No. 2008-266112 discloses a method for separating a semiconductive CNT from a metallic CNT at a material level using centrifugal separation, and Japanese Laid-open Patent Publication No. 2011-166070 discloses a method for causing metal microparticles to selectively adhere to a metallic CNT in a channel by electrophoresis at a device level, and cutting only the metallic CNT by a chemical reaction.

On the other hand, since graphene has extremely high mobility, it is expected to apply to a high speed transistor. However, the graphene that is a two-dimensional material has a zero band gap and provides metallic properties, and thus a current on/off ratio of the transistor sufficient for practical use cannot be obtained. Thus, a method for cutting a graphene sheet into graphene nanoribbons (GNR) of several nm to several tens of nm wide strips to introduce a band gap by quantum confinement has been widely tried.

The GNR provides different properties depending on longitudinal edge structures. For an arm chair type with carbon atoms at a longitudinal edge of the GNR being arranged at a two-atom period, the GNR provides semiconductive properties, and for a zigzag type with the carbon atoms being arranged in a zigzag manner, the GNR provides metallic properties.

When a semiconductive GNR is used as a channel of a field-effect transistor, uniformity of ribbon widths or edge structures (particularly of the arm chair type) is required to obtain high mobility and a sufficient current on/off ratio.

In recent years, J. Cai et al., Nature 466, 470 (2010) has reported a method for forming a semiconductive GNR with ribbon widths and edge structures of an arm chair type uniformed at an atomic level, from an organic molecular precursor based on bottom-up approach.

To improve performance of the TFT using the CNT network, it is important to separate the semiconductive CNT and the metallic CNT from the CNT hybrid. However, even though the methods are used as in Japanese Laid-Open Patent Publication No. 2008-266112 or Japanese Laid-open Patent Publication No. 2011-166070 described above, it is extremely difficult to separate the CNTs completely. Thus, in the TFT using the CNT network as a channel, the metallic CNT that is not completely removed forms a current path between source and drain to increase an off current, thereby reducing an on/off ratio. Also, the metallic CNT remaining in the channel may increase variations in electric properties of the TFT.

### SUMMARY

A graphene film of the present embodiment constitutes a network structure with a plurality of ribbon-shaped graphenes having a longitudinal edge structure of an arm chair type.

An electronic device of the present embodiment includes: an insulating material; a graphene film formed above the insulating material; and an electrode formed under or on the graphene film above the insulating material, and the graphene film constitutes a network structure with a plurality of ribbon-shaped graphenes having a longitudinal edge structure of an arm chair type.

A method for manufacturing an electronic device of the present embodiment includes: forming, above an insulating material, a graphene film with a plurality of ribbon-shaped graphenes having a longitudinal edge structure of an arm chair type constitute a network structure; and forming an electrode under or on the graphene film above the insulating material.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a GNR film according to a first embodiment;

FIG. 2 is a partially enlarged schematic plan view of a structure illustrating a GNR that constitutes the GNR film according to the first embodiment;

FIG. 3 is a photograph illustrating a scanning tunneling microscope image of the GNR film according to the first embodiment;

FIG. 4A to FIG. 4C are diagrams illustrating a method for manufacturing a top gate top contact TFT in the sequence of steps according to a second embodiment;

FIG. 5A to FIG. 5B are diagrams illustrating the method for manufacturing the top gate top contact TFT in the sequence of steps according to the second embodiment, following to FIG. 4C;

FIG. 6A to FIG. 6C are schematic sectional views illustrating a method for manufacturing a bottom gate top contact TFT in the sequence of steps according to a third embodiment;

FIG. 7A to FIG. 7B are schematic sectional views illustrating the method for manufacturing the bottom gate top contact TFT in the sequence of steps according to the third embodiment, following to FIG. 6C; and

FIG. 8A to FIG. 8D are schematic sectional views illustrating a method for manufacturing a top gate top contact TFT in the sequence of steps according to a fourth embodiment.

### DESCRIPTION OF EMBODIMENTS

Now, embodiments to which the present embodiment is suitably applied will be described in detail with reference to the drawings. In the drawings, some components are not precisely illustrated with relatively to its sizes or thicknesses or the like for convenience of illustration.

### First Embodiment

In this embodiment, a configuration of a GNR film and a method for manufacturing the GNR film will be described.

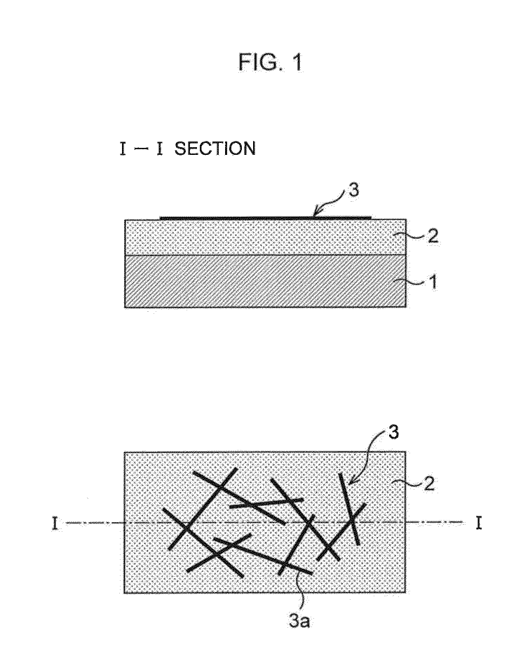

FIG. 1 is a diagram of the GNR film according to the first embodiment, a lower view is a plan view, and an upper view is a sectional view taken along a dashed-dotted line I-I in the plan view.

First, an insulating substrate 1 is prepared to form a metal film 2 having a (111) crystal plane on the insulating substrate 1.

The insulating substrate 1 may include, as an insulating crystal substrate, for example, a mica substrate, a c-plane sapphire (α-Al₂O₂) crystal substrate, an MgO (111) crystal substrate, or the like, and the mica substrate is used in this embodiment.

As a metal film material, at least one of the materials selected from Au, Ag, Cu, Co, Ni, Pd, Ir, Pt, or the like may be used. Selecting a type of a substrate can provide an epitaxial crystal plane of the metals. In this embodiment, Au is used as the metal film material. It is well known that Au has high orientation in a (111) plane on the mica substrate.

Specifically, the insulating substrate 1 that is the mica substrate is first cleaved in the air to obtain a clean surface of the insulating substrate 1.

Then, the insulating substrate 1 is introduced into a vacuum chamber (a basic degree of vacuum: 1×10⁻⁷ Pa or less), and annealed at a temperature of about 300° C. to 500° C. for 12 to 24 hours.

Next, while maintaining the temperature in annealing, an Au thin film having a film thickness of about 100 nm to 200 nm is deposited on the insulating substrate 1 at a vapor deposition rate of about 0.05 nm/s to 1.0 nm/s by vapor deposition.

To increase adhesion between the Au thin film and the insulating substrate 1, Ti having a film thickness of about 0.5 nm to 1 nm may be deposited between the Au thin film and the insulating substrate 1. The deposition method of the metal film material may include, other than the vapor deposition, sputtering, pulse laser deposition, molecular beam epitaxy, or the like.

Here, a heating temperature of the insulating substrate 1 is set to 450° C., and an Au thin film having a film thickness of about 100 nm was deposited by vapor deposition. The vapor deposition rate is set to about 1.0 nm/s for an Au thin film having a film thickness of 0 nm to 50 nm, and about 0.05 nm/s for an Au thin film having a film thickness of 50 nm to 100 nm.

The Au thin film formed on the insulating substrate 1 by the above-described method is subjected to a plurality of surface cleaning cycles of the Au thin film including Ar ion sputtering and ultrahigh vacuum annealing as one set. The surface cleaning provides a 23×3^{1/2} reconstructed surface of Au (111) and further improve its flatness at an atomic level.

In one set of surface cleaning, Ar ion sputtering is performed for one minute with an ion acceleration voltage of 0.8 kV and an ion current of 1.0 μA, and annealing is performed for ten minutes at about 400° C. while maintaining a degree of vacuum of 5×10⁻⁷ Pa or less. In this embodiment, four cycles of surface cleaning are performed.

From the above, the metal film 2 having an Au(111) surface is formed on the insulating substrate 1.

Then, a GNR film 3 is formed on the metal film 2.

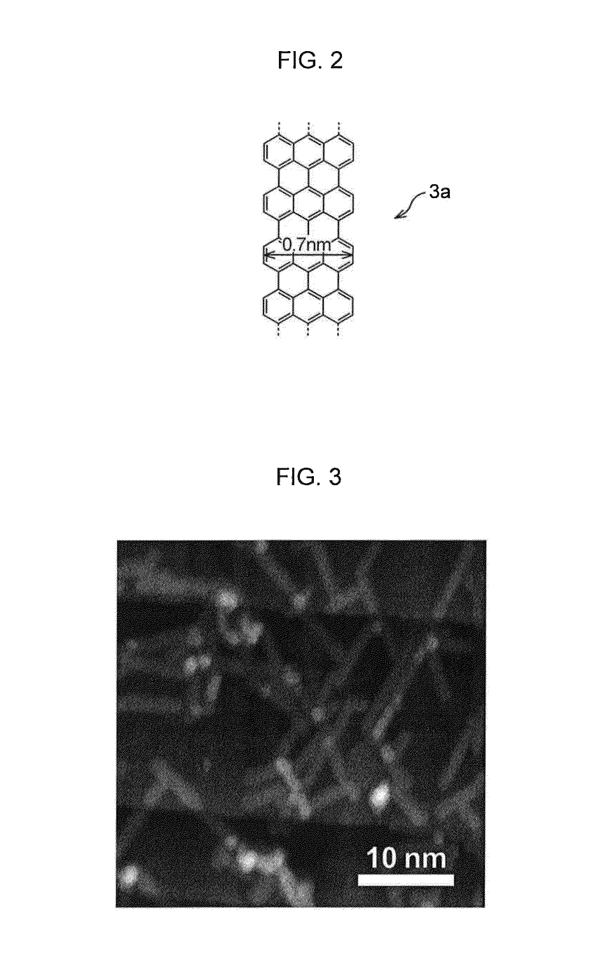

Specifically, a plurality GNRs 3a are formed in a network on the Au(111) surface of the metal film 2 to form the GNR film 3. As illustrated in the partially enlarged view in FIG. 2, the GNR 3a includes three or more six-membered rings (benzene rings) of carbon atoms bonded in parallel in a short direction, and a longitudinal edge structure of a complete arm chair type. In this embodiment, an anthracene GNR including three benzene rings bonded and a ribbon width (a dimension of the short direction) of about 0.7 nm is formed as the GNR 3a,

To form the GNR film 3, a network constituted by the plurality of GNRs 3a is formed in situ on the Au(111) surface of the metal film 2 in a vacuum chamber having an ultra high degree of vacuum without exposing the insulating substrate 1 and the metal film having been subjected to the surface cleaning to the air.

Here, an anthracene precursor (10,10′-dibromo-9,9′-bianthryl molecule) including, as a basic skeleton, an organic molecules with three six-membered rings being arranged is vapor deposited on the Au(111) surface of the metal film 2 to form a network structure of the anthracene GNR 3a by thermal energy generated by heating the substrate.

The temperature of the substrate is maintained at about 200° C. to 250° C., and under an ultrahigh vacuum of 5×10⁻⁸ Pa or less, the anthracene precursor is heated to about 200° C. to 250° C. using a K-cell type evaporator and vapor deposited on the Au(111) surface of the metal film 2. A vapor deposition rate is about 0.1 nm/min to 1.0 nm/min, a vapor deposition time is about 1 minute to 3 minutes, and a vapor deposition film thickness is about 1 ML to 3 ML (ML: monolayer, 1 ML=about 0.2 nm).

On the insulating substrate 1 of about 200° C. to 250° C., the anthracene precursor forms a polymer chain linearly coupled by debromination and radical polymerization. Then, the insulating substrate 1 is increased in temperature to about 400° C. to 450° C. and maintain the temperature for 5 minutes to 20 minutes, and form the anthracene GNR 3a by dehydrogenation and cyclization.

Adjacent individual anthracene GNR 3a coming into contact to form a network structure significantly depends on a vapor deposition rate and a vapor deposition film thickness of the precursor, and a distance between a vapor deposition source and the insulating substrate 1. Thus, such conditions need to be adjusted for each vapor deposition device, accordingly.

FIG. 3 illustrates a scanning tunneling microscope image of the GNR film 3 formed by the above described method. The network of the anthracene GNR can be seen on a terrace of the Au(111).

Besides the anthracene precursor, a pentacene precursor including five six-membered rings, a heptacene precursor including seven six-membered rings, and a nonacene precursor including nine six-membered rings may be used to form a GNR network structure constituted by a pentacene GNR, a heptacene GNR, and a nonacene GNR.

A ribbon width of the pentacene GNR is about 1.2 nm, a ribbon width of the heptacene GNR is about 1.7 nm, and a ribbon width of the nonacene GNR is about 2.2 nm.

Generally, it has been found that a band gap of the GNR is inversely proportional to the ribbon width. The type of the precursor, that is, a ribbon width of an individual GNR that forms the network may be selected according to a desired size of a band gap or desired TFT properties.

As described above, according to this embodiment, a GNR film 3 is obtained that provides complete semiconductive properties of the individual anthracene GNR 3a without mixing of metallic properties, reduces an off current, achieves excellent properties with field-effect mobility of several tens to several hundreds of cm²/Vs at a high current on/off ratio of 10⁵ or more sufficient for practical use, and prevents variations in electric properties.

### Second Embodiment

In this embodiment, a configuration of a top gate top contact TFT that uses a GNR film as a channel and a method for manufacturing the top gate top contact TFT will be described.

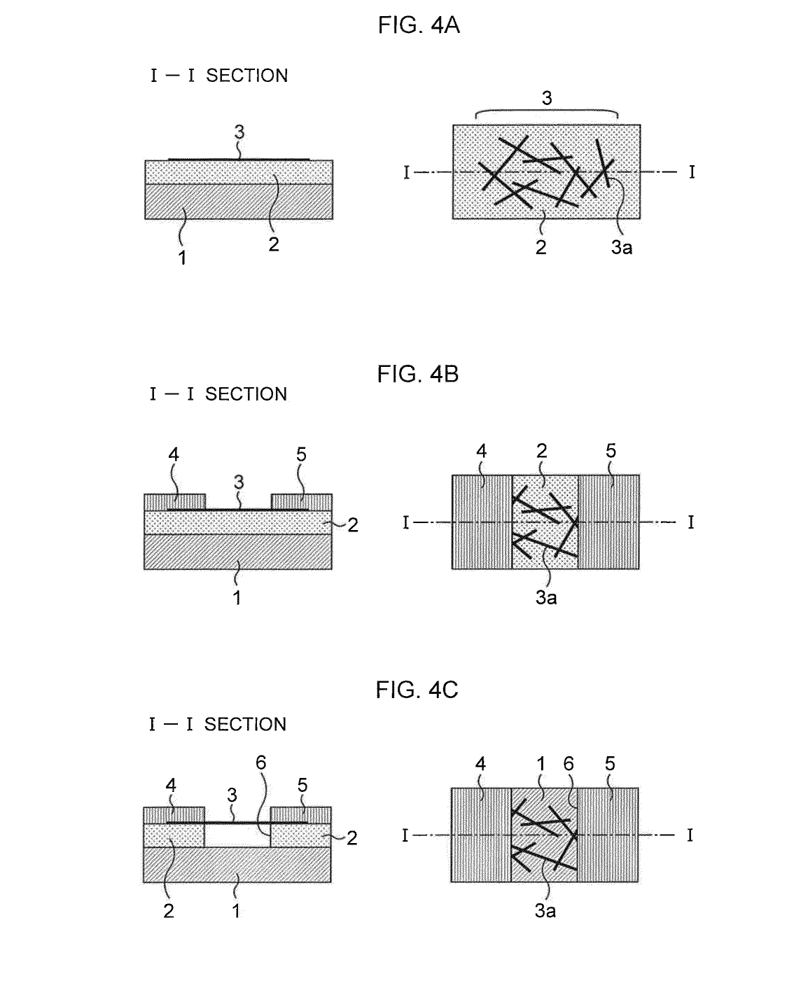

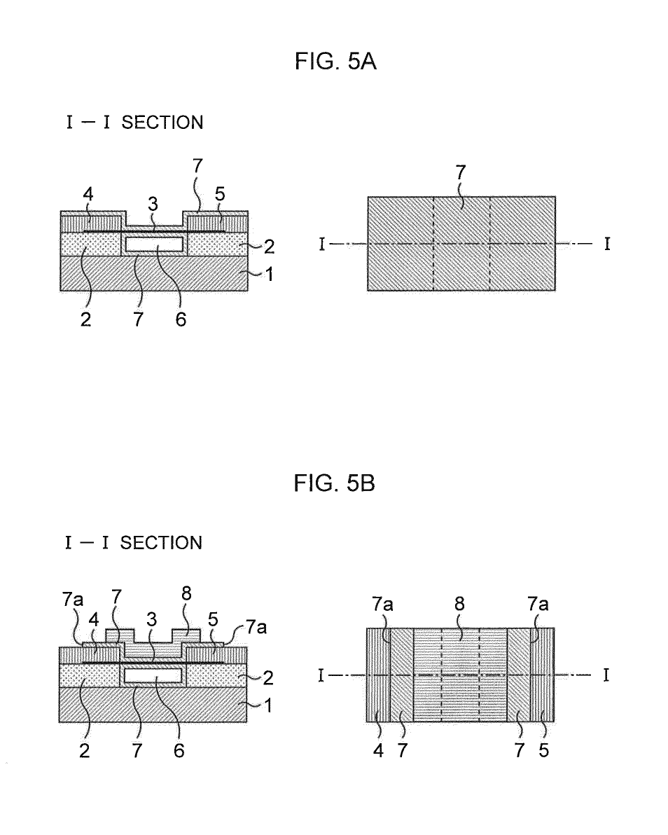

FIGS. 4 and 5 are diagrams illustrating the method for manufacturing the top gate top contact TFT in the sequence of steps according to a second embodiment. In each figure, a right view is a plan view, and a left view is a sectional view taken along a dashed-dotted line I-I in the plan view.

First, through the steps in FIG. 1 described in the first embodiment, a metal film 2 is formed on an insulating substrate 1, and a GNR film 3 that is a network of an anthracene GNR 3a is formed on the metal film 2. The GNR film 3 is a channel of a top gate top contact TFT. This state is illustrated in FIG. 4A.

In this embodiment, instead of the anthracene GNR 3a, any of a pentacene GNR, a heptacene GNR, and a nonacene GNR may be formed as the GNR.

Next, with reference to FIG. 4B, a source electrode 4 and a drain electrode 5 connected to opposite ends of the GNR film 3 as a channel are formed on the metal film 2 and the GNR film 3 by using electron lithography, vapor deposition, and lift-off.

As described later, the metal film 2 other than in lower layer regions of the source electrode 4 and the drain electrode 5 is removed by wet etching as a post-step. Thus, a metal species used for the source electrode 4 and the drain electrode 5 requires sufficient etching resistance to a metal species for the metal film 2. When an HNO₃+HCl mixed aqueous solution is used for wet etching of an Au(111), Cr and Ti that are less soluble in the etchant are suitable as the metal species for the source electrode 4 and the drain electrode 5.

First, a two layer resist for forming the source electrode 4 and the drain electrode 5 is spin coated on the metal film 2 and the GNR film 3. A resist of a trade name PMGI SFG2S (manufactured by MichroChem Corp.) is used as a sacrifice layer resist of a lower layer, and a resist of a trade name ZEP520A (manufactured by Zeon Corporation) diluted with a resist of a trade name ZEP-A (manufactured by Zeon Corporation) at 1:1 is used as an electron beam resist.

Then, a resist pattern having a distance of about 10 nm to 50 nm between the source electrode 4 and the drain electrode 5 is formed by electron beam lithography, and then, for example, Ti and Cr as electrode materials are sequentially deposited by vapor deposition under a high vacuum of 1×10⁻⁵ Pa or less. For Ti, a vapor deposition rate is about 0.05 nm/s to 0.1 nm/s and a film thickness is about 1 nm, and for Cr, a vapor deposition rate is about 0.1 nm/s to 1 nm/sand a film thickness is about 30 nm.

The deposition method of the electrode material may include, not limited to the vapor deposition, sputtering, pulse laser deposition, or the like.

After deposition of the electrode material, the electrode material is lifted off to form the source electrode 4 and the drain electrode 5.

Then, as illustrated in FIG. 4C, the metal film 2 other than in the lower layer regions of the source electrode 4 and the drain electrode 5 is removed by wet etching. Thus, a gap 6 is formed between the insulating substrate 1 and the GNR film 3.

Here, for the wet etching of the metal film 2, a mixed aqueous solution of HNO₃ (6.5 vol %)+HCl (17.5 vol %) at about 60° C. is used as an etchant.

In the structure in FIG. 4C obtained by the wet etching, the channel bridges the electrodes and is easily cut. Thus, washing and drying after the wet etching need to be meticulously performed. Here, washing with pure water and rinsing with isopropyl alcohol are sequentially performed, and in the subsequent drying, supercritical drying using a CO₂ gas is performed to prevent the channel from being cut by surface tension or a capillary force of the solution.

Then, as illustrated in FIG. 5A, a gate insulating film 7 is formed using atomic layer deposition (ALD). Here, as the gate insulating film, for example, HfO₂ having a film thickness of about 5 nm to 10 nm is formed. As conditions for the ALD, tetrakis (dimethyl amino) hafnium and H₂O are used as precursors, and a deposition temperature is about 250° C.

In the ALD, there is no directivity in a deposition direction, and thus as illustrated in FIG. 5A, HfO₂ is formed to cover the entire channel and further cover an inner wall surface of the gap 6. In the top gate top contact TFT, the HfO₂ on the upper surface of the channel functions as the gate insulating film 7.

As other gate insulting films, Al₂O₃, Si₃N₄, HfSiO, HfAlON, Y₂O₃, SrTiO₃, PbZrTiO₃, BaTiO₃ or the like maybe used. A method for forming such films is not particularly limited, but may be selected according to the type of the insulating film.

Then, as illustrated in FIG. 5B, a gate electrode 8 is formed on the gate insulating film 7.

Specifically, a resist pattern of the gate electrode 8 is formed by electron beam lithography similarly as to the above-described step of forming the source electrode 4 and the drain electrode, and the gate electrode 8 is formed by vapor deposition and lift-off. The gate electrode 8 is formed into a two-layer structure of Cr/Ti, for example, under the vapor deposition condition and with the film thickness similar to those of the source electrode 4 and the drain electrode 5.

Next, an electrode opening 7a for conduction with the source electrode 4 and the drain electrode 5 is formed in the gate insulating film 7.

An electrode opening pattern formed of a single-layer resist of a trade name ZEP520A (manufactured by Zeon Corporation) is formed by the electron beam lithography, and HfO₂ exposed from the electrode opening pattern is removed by reactive ion etching using a chlorinated mixed gas (for example, BCl₃+Cl+O₂). From the above, the electrode opening 7a is formed in the gate insulating film 7.

From the above, the top gate top contact TFT is obtained using, as a channel, the GNR film 3 that is a network of the anthracene GNR 3a.

As described above, according to this embodiment, a reliable top gate top contact TFT is achieved including, as a channel, the GNR film 3 that provides complete semiconductive properties of the individual anthracene GNR 3a without mixing of metallic properties, reduces an off current, achieves excellent properties with field-effect mobility of several tens to several hundreds of cm²/Vs at a high current on/off ratio of 10⁵ or more sufficient for practical use, and prevents variations in electric properties.

### Third Embodiment

In this embodiment, a configuration of a bottom gate top contact TFT that uses a GNR film as a channel and a method for manufacturing the bottom gate top contact TFT will be described.

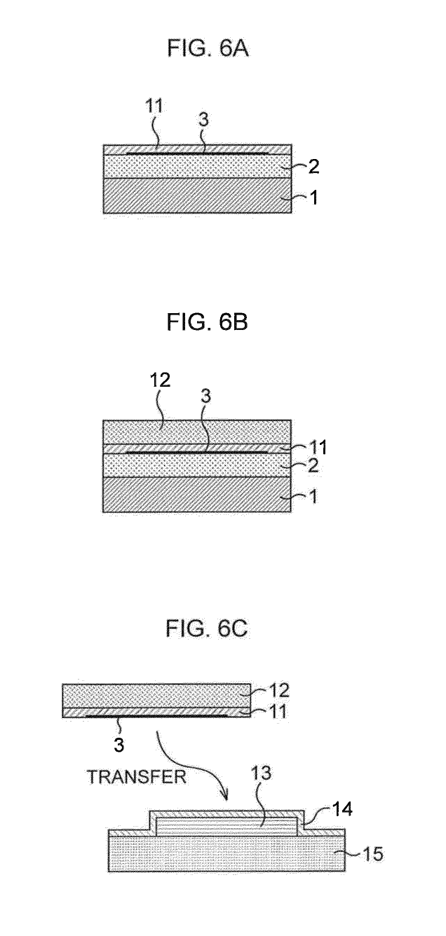

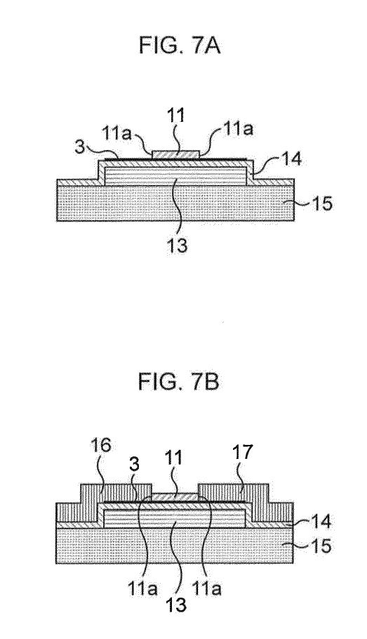

FIGS. 6 and 7 are schematic sectional views illustrating the method for manufacturing the bottom gate top contact TFT in the sequence of steps according to a third embodiment.

First, as illustrated in FIG. 6A, through the steps in FIG. 1 described in the first embodiment, a metal film 2 is formed on an insulating substrate 1, and a GNR film 3 that is a network of an anthracene GNR 3a is formed on the metal film 2.

In this embodiment, instead of the anthracene GNR 3a, any of a pentacene GNR, a heptacene GNR, and a nonacene GNR may be formed as the GNR.

Next, a protective film 11 is formed on the metal film 2 so as to cover the GNR film 3. The protective film 11 is made of, for example, Cr₂O₃.

Specifically, after the GNR film 3 is formed on the metal film 2, a Cr film is formed in situ on the GNR film 3 by vapor deposition without being exposed from a vacuum chamber. A vapor deposition rate is about 0.01 nm/s to 0.05 nm/s, and a film thickness is about 1 nm to 3 nm. Next, the Cr film is exposed to the air, naturally oxidized, and thus made into an oxide. (Cr₂O₃) to form the protective film 11. As described later, the protective film 11 has a function of protecting a channel from residues of an organic support film used for transfer of a channel.

The protective film 11 needs to have both a property of being easily oxidized and insulated, and a property of being hardly chemically bonded to C that constitutes the GNR 3a.

As the material for the protective film 11, besides CrO₂O₃, for example, SiO₂, Al₂O₃, Sc₂O₃, MnO₂, ZnO, Y₂O₃, ZrO₂, MoO₃, or RuO₂ may be used. On the other hand, Ti or Ni are easily oxidized to be TiO₂ or NiO, and if TiO₂ or NiO is deposited on the GNR, TiCx or NiCx is unsuitably formed on an interface to influence a physical property of the GNR.

Then, as illustrated in FIG. 6B, a support film 12 is formed on the protective film 11. The support film 12 is formed by spin coating polymethyl methacrylate (PMMA) of acrylic resin to have a film thickness of about 100 nm to 500 nm.

Besides PMMA, the support film may include an epoxy resin, a thermal release tape, an adhesive tape, various photoresists or electron beam resists, or a laminated film thereof.

Then, as illustrated in FIG. 6C, the metal film 2 is removed by wet etching using, for example, a HNO₃+HCl mixed aqueous solution, and a structure constituted by the support film 12, the protective film 11, and the GNR film 3 is separated from the insulating substrate 1.

Next, the structure is subjected to pure water washing and drying, and then the structure is transferred on a transfer insulating substrate 15, having a gate electrode 13 and a gate insulating film 14 covering the gate electrode 13 formed on an upper surface, so that the GNR film 3 comes into contact with the gate insulating film 14.

After the transfer, the support film 12 is removed by being immersed in acetone at about 70° C., and rinsed with isopropyl alcohol.

Generally, it is known that completely removing PMMA on graphene is difficult, and PMMA degrades properties of graphene. In this embodiment, the protective film 11 is formed on the GNR film 3, thereby preventing residues of PMMA on the support film 12 from directly adhering on the GNR film 3.

Here, as the transfer insulating substrate 15, for example, a Si substrate having a thermally-oxidized film formed on a surface is used. Also, as in the second embodiment, the gate electrode 13 of Cr/Ti is formed by using electron beam lithography, vapor deposition, and lift-off, and then the gate insulating film 14 of HfC₂ is formed by ALD so as to cover the gate electrode 13.

The transfer insulating substrate 15 is not limited other than requiring flatness, and for example, a transparent glass substrate, a flexible PET substrate, or the like may be used for application to a display or the like. Also, the gate electrode 13, and further a metal species for a source electrode and a drain electrode described later are not particularly limited, but transparent electrode materials such as Au/Ti, Pt/Ti, Pd/Ti, or ITO (indium tin oxide), In₂O₃, SnO₂, AlZnO, or GaZnO may be used.

Then, an electrode resist pattern for forming the source electrode and the drain electrode is formed by electron beam lithography. Here, a distance between the source electrode and the drain electrode is set to about 10 nm to 50 nm. For conduction between the source electrode and the drain electrode and the channel, as illustrated in FIG. 7A, regions of the protective film 11 on which the source electrode and the drain electrode are formed are removed by wet etching to form electrode openings 11a. As an etchant, for example, eerie ammonium nitrate is used.

Then, as illustrated in FIG. 7B, Cr/Ti is vapor deposited and lifted off similarly to the method for forming the gate electrode 13 to form a source electrode 16 and a drain electrode 17.

From the above, the bottom gate top contact TFT is obtained by a transfer method using, as a channel, the GNR film 3 that, is a network of the anthracene GNR 3a.

As described above, according to this embodiment, a reliable bottom gate top contact TFT is achieved including, as a channel, the GNR film 3 that provides complete semiconductive properties of the individual anthracene GNR 3a without mixing of metallic, properties, reduces an off current, achieves excellent properties with field-effect mobility of several tens to several hundreds of cm²/Vs at a high current on/off ratio of 10⁵ or more sufficient for practical use, and prevents variations in electric properties.

### Fourth Embodiment

In this embodiment, a configuration of a top gate top contact TFT that uses a GNR film as a channel and a method for manufacturing the top gate top contact TFT will be described.

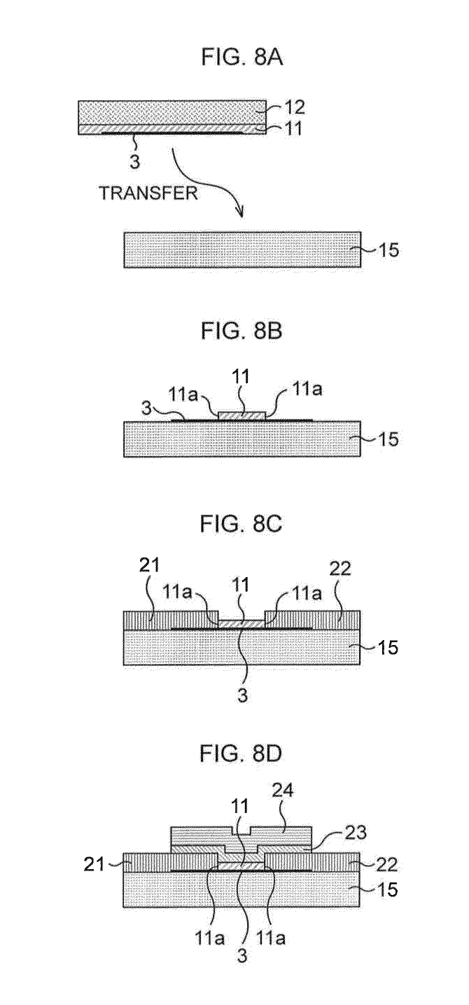

FIG. 8A to 8D are schematic sectional view illustrating the method for manufacturing the top gate top contact TFT in the sequence of steps according to a fourth embodiment.

First, steps as in FIGS. 6A and 6B in the third embodiment are performed.

Then, as illustrated in FIG. 8A, as in the third embodiment, a metal film 2 is removed by wet etching using, for example, a HMO₃+HCl mixed aqueous solution, and a structure, constituted by a support film 12, a protective film 11, and a GNR film 3 is separated from an insulating substrate 1.

Next, as in the third embodiment, the structure is subjected to pure water washing and drying, and then the structure is transferred on a transfer insulating substrate 15 so that a GNR film 3 comes into contact with an upper surface of the transfer insulating substrate 15.

After the transfer, a support film 12 is removed by being immersed in acetone at about 70° C., and rinsed with isopropyl alcohol.

Then, as in the third embodiment, an electrode resist pattern for forming a source electrode and a drain electrode is formed by electron beam lithography. Here, a distance between the source electrode and the drain electrode is set to about 10 nm to 50 nm. For conduction between the source electrode and the drain electrode and the channel, as illustrated in FIG. 8B, regions of the protective film 11 on which the source electrode and the drain electrode are formed are removed by wet etching to form electrode openings 11a.

Then, as illustrated in FIG. 8C, for example, Cr/Ti is vapor deposited and lifted off to form a source electrode 21 and a drain electrode 22.

Next, as illustrated in FIG. 8D, a resist pattern of a gate stack is formed by electron beam lithography, and a gate insulating film 23 and a gate electrode 24 are sequentially formed by vapor deposition.

As the gate insulating film 23, for example, HfO₂ having a film thickness of about 5 nm to 10 nm is used. An O₂ gas is introduced into a vacuum of 1×10⁻⁵ Pa or less to vapor deposition Hf, and thus the gate insulating film 23 of HfO₂ that is an oxide of Hf is formed. On the gate electrode 24, for example, Cr/Ti is vapor deposited similarly to the source electrode 21 and the drain electrode 22. Then, Cr/Ti is lifted off to form a gate stack structure of the gate insulating film 23 and the gate electrode 24 on the gate insulating film 23.

From the above, the top gate top contact TFT is obtained by a transfer method using, as a channel, the GNR film 3 that is a network of the anthracene GNR 3a.

As described above, according to this embodiment, a reliable top gate top contact TFT is achieved including, as a channel, the GNR film 3 that provides complete semi conductive properties of the individual anthracene GNR 3a without mixing of metallic properties, reduces an off current, achieves excellent properties with field-effect mobility of several tens to several hundreds of cm²/Vs at a high current on/off ratio of 10⁵ or more sufficient for practical use, and prevents variations in electric properties.

According to the present embodiment, a graphene film that provides complete semiconductive properties without mixing of metallic properties, reduces an off current, achieves a high current on/off ratio of 10⁵ or more sufficient for practical use, and prevents variations in electric properties, and a reliable electronic device including the graphene film are obtained.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A graphene film wherein a plurality of ribbon-shaped graphenes having a longitudinal edge structure of an arm chair type constitute a network structure.

2. The graphene film according to claim 1, wherein the graphene includes three or more six-membered rings of carbon atoms bonded in parallel in a short direction.

3. The graphene film according to claim 2, wherein the graphene has a width of 0.7 nm or more in a portion in which three or more six-membered rings of carbon atoms are bonded in parallel in a short direction.

4. An electronic device comprising:
an insulating material;
a graphene film formed above the insulating material; and
an electrode formed under or on the graphene film above the insulating material,
wherein in the graphene film, a plurality of ribbon-shaped graphenes having a longitudinal edge structure of an arm chair type constitute a network structure.

5. The electronic device according to claim 4, wherein the graphene includes three or more six-membered rings of carbon atoms bonded in parallel in a short direction.

6. The electronic device according to claim 5, wherein the graphene has a width of 0.7 nm or more in a portion in which three or more six-membered rings of carbon atoms are bonded in parallel in a short direction.

7. The electronic device according to claim 4, wherein the insulating material is an insulating crystal substrate.

8. A method for manufacturing an electronic device comprising:
forming, above an insulating material, a graphene film in which a plurality of ribbon-shaped graphenes having a longitudinal edge structure of an arm chair type constitute a network structure; and
forming an electrode under or on the graphene film above the insulating material.

9. The method for manufacturing an electronic device according to claim 8, wherein the graphene includes three or more six-membered rings of carbon atoms bonded in parallel in a short direction.

10. The method for manufacturing an electronic device according to claim 9, wherein the graphene has a width of 0.7 nm or more in a portion in which three or more six-membered rings of carbon atoms are bonded in parallel in a short direction.

11. The method for manufacturing an electronic device according to claim 8, wherein the graphene film, is formed on a metal film formed on the insulating materials, and
an area of the metal film located under the graphene film is partially removed.

12. The method for manufacturing an electronic device according to claim 8, wherein the insulating material is an insulating crystal substrate.
